(19) United States
(12) Patent Application Publication
(10) Pub. No.: US 2005/0195576 A1
(43) Pub. Date: Sep. 8, 2005

(54) Housing assembly for an electronic device

(75) Inventor: Ko-Chien Chuang, Taipei City (TW)

Correspondence Address: BACON & THOMAS, PLLC, 625 SLATERS LANE, FOURTH FLOOR, ALEXANDRIA, VA, 22314, US

(73) Assignee: COMPAL ELECTRONICS, INC., Taipei City (TW)

(21) Appl. No.: 10/612,006

(22) Filed: Jul. 3, 2003

(51) Int. Cl. H05K 5/00

(52) U.S. Cl. 361/730; 361/755

(57) ABSTRACT

In a housing assembly for an electronic device, a pivot housing is connected pivotally to a pivot side of a base housing, has an inner surface opposite to an outer operating surface, and is rotatable relative to the base housing about a first axis such that the pivot housing is operable so as to move from a closed position, where the inner surface of the pivot housing is disposed to confront an inner operating surface of the base housing, to an open position, where the inner surface of the pivot housing is spaced apart from the inner operating surface of the base housing. A rotatable main housing is disposed adjacent to the base and pivot housings, is connected rotatably to the pivot housing, and is rotatable relative to the pivot housing about a second axis parallel to the first axis when the pivot housing is disposed in the open position.

### BACKGROUND OF THE INVENTION

1. Field of the Invention

The invention relates to a housing, more particularly to a housing assembly for an electronic device.

2. Description of the Related Art

FIG. 1 illustrates a conventional personal digital assistant 10 that includes a touch-control display screen 101, which can be used as a visual interface or serve as an input device. Since the conventional personal digital assistant has a relatively small size, the small handwriting area thereof results in inconvenience during data input.

Conventional portable electronic devices, such as a mobile phone, a personal digital assistant, a electronic dictionary, a digital camera, etc., are handy consumer items. However, it is inconvenient to carry and use such electronic devices at the same time.

### SUMMARY OF THE INVENTION

Therefore, the object of the present invention is to provide a housing assembly for a multi-function electronic device that is convenient to carry.

According to the present invention, there is provided a housing assembly for an electronic device. The housing assembly comprises:

a base housing having a pivot side and an inner operating surface;

a pivot housing connected pivotally to the pivot side of the base housing and having an outer operating surface, and an inner surface opposite to the outer operating surface, the pivot housing being rotatable relative to the base housing about a first axis such that the pivot housing is operable so as to move from a closed position, where the inner surface of the pivot housing is disposed to confront the inner operating surface of the base housing, to an open position, where the inner surface of the pivot housing is spaced apart from the inner operating surface of the base housing; and

a rotatable main housing disposed adjacent to the base housing and the pivot housing and connected rotatably to the pivot housing, the main housing being rotatable relative to the pivot housing about a second axis parallel to the first axis when the pivot housing is disposed in the open position.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic view of a conventional personal digital assistant;

FIG. 2 is a perspective view showing the preferred embodiment of a housing assembly for an electronic device according to the present invention;

FIG. 3 is a perspective view showing the preferred embodiment in a first state of use;

FIG. 4 is a perspective view showing the preferred embodiment in a second state of use;

FIG. 5 is a perspective view showing the preferred embodiment in a third state of use; and

FIG. 6 is a perspective view showing the preferred embodiment in a fourth state of use.

### DETAILED DESCRIPTION OF THE PREFERRED EMBODIMENT

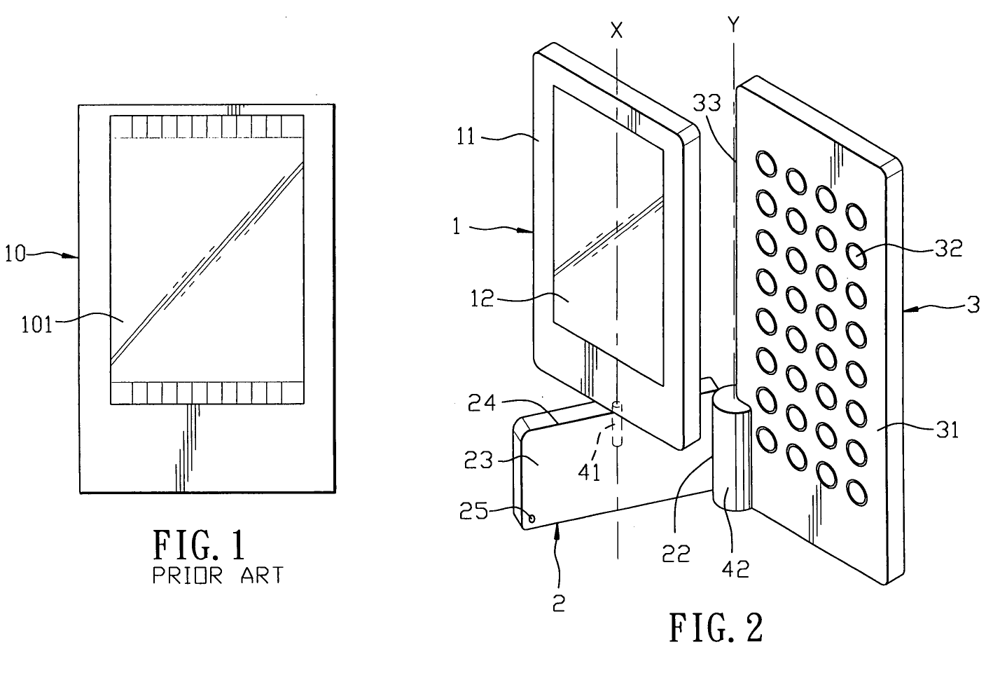

Referring to FIG. 2, the preferred embodiment of a housing assembly for an electronic device according to the present invention is shown to include a base housing 3, a pivot housing 2, and a rotatable main housing 1. In this embodiment, the electronic device is a multi-function device that integrates the functions of a personal digital assistant, a mobile phone, a camera and an electronic dictionary.

The base housing 3, which is rectangular, has a pivot side 33 and an inner operating surface 31. In this embodiment, the inner operating surface 31 is adapted to be mounted with a keypad 32 thereon.

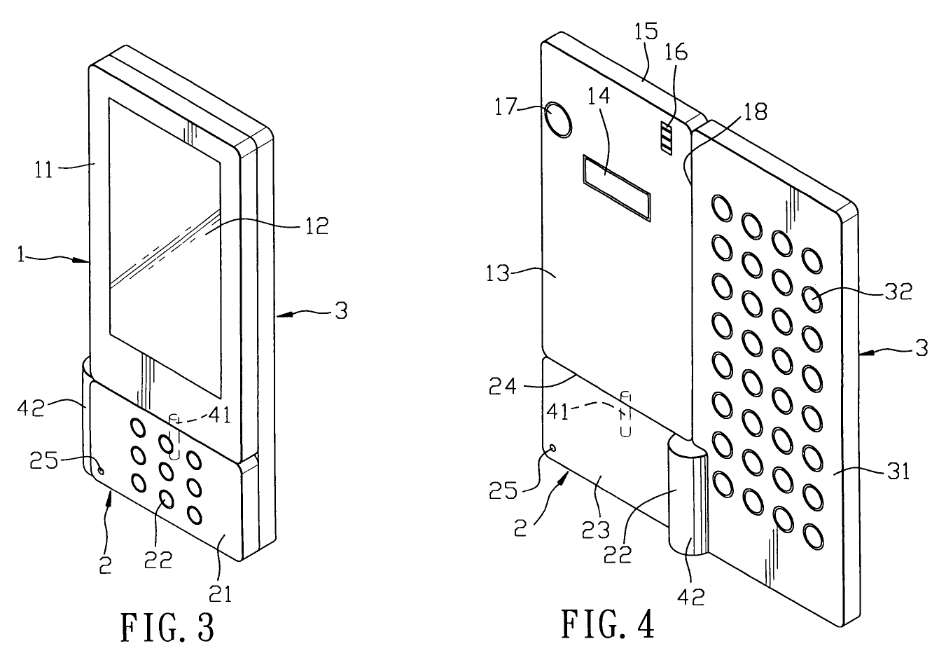

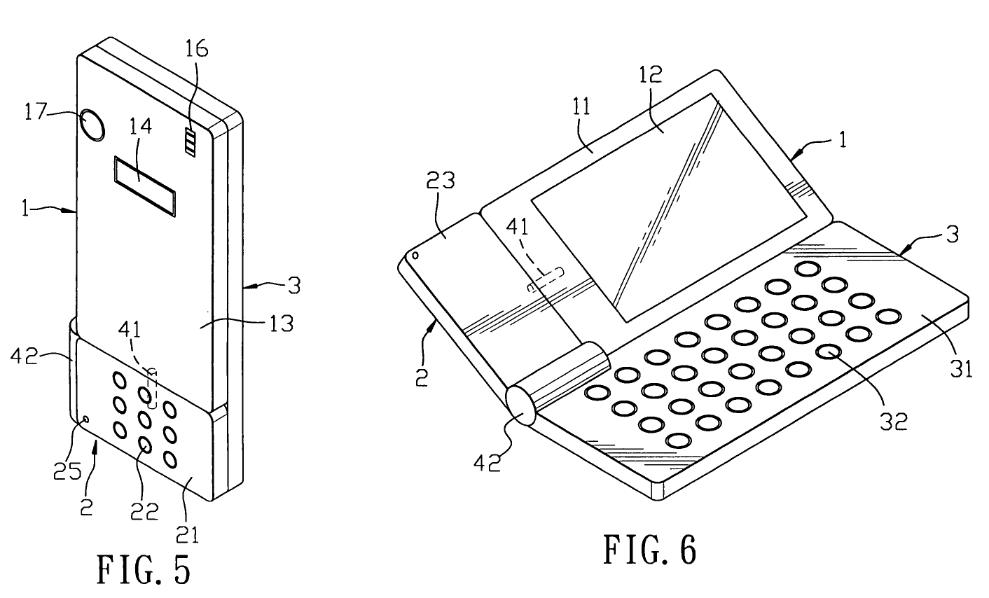

The pivot housing 2, which is rectangular, has a first side 22 connected pivotally to the pivot side 33 of the base housing 3 by means of a hinge device 42, a second side 24 transverse to the first side 22, an outer operating surface 21 (see FIG. 3), and an inner surface 23 opposite to the outer operating surface 21. The pivot housing 2 is rotatable relative to the base housing 3 about a first axis (Y) such that the pivot housing 2 is operable so as to move from a closed position, where the inner surface 23 of the pivot housing 2 is disposed to confront the inner operating surface 31 of the base housing 3 (see FIGS. 3 and 5), to an open position, where the inner surface 23 of the pivot housing 2 is spaced apart from the inner operating surface 31 of the base housing 3 (see FIGS. 2, 4 and 6). In this embodiment, the outer operating surface 21 is adapted to be mounted with a set of function keys 22 thereon, as best shown in FIG. 3. Each of the outer operating surface 21 and the inner surface 23 is formed with a microphone sound hole 25, as shown in FIGS. 3 and 4.

The main housing 1, which is rectangular, is disposed adjacent to the base housing 3 and the pivot housing 2, and is connected rotatably to the second side 24 of the pivot housing 2 by means of a pivot axle 41. The main housing 1 is rotatable relative to the pivot housing 2 about a second axis (X) parallel to the first axis (Y) when the pivot housing 2 is disposed in the open position, as shown in FIG. 2. In this embodiment, the main housing 1 has opposite surfaces 11, 13. The surface 11 is adapted to be mounted with a first display 12 of the electronic device thereon (see FIG. 3). The surface 13 is adapted to be mounted with a second display 14 and a camera lens 17 of the electronic device thereon (see FIG. 4). The surface 13 is further formed with a speaker sound hole 16. The main housing 1 further has a third side 18 parallel to the pivot side 33 of the base housing 3 and transverse to the second side 24 of the pivot housing 2. The pivot side 33 of the base housing 3 has a length equal to the sum of a length of the third side 18 of the main housing 1 and that of the first side 22 of the pivot housing 2.

In actual use, when the pivot housing 2 is disposed in the closed position, and when the surface 11 of the main housing 1 is flush with the outer operating surface 21 of the pivot housing 2, the housing assembly can be used as a personal digital assistant as a result of the presence of the first display 12 and the function keys 22, as shown in FIG. 3. When the pivot housing 2 is disposed in the closed position, and when the surface 13 of the main housing 1 is flush with the outer operating surface 21 of the pivot housing 2, the housing assembly can be used as a digital camera or a mobile phone as a result of the presence of the second display 14, the function keys 22 and the camera lens 17, as shown in FIG. 5. When the pivot housing 2 is disposed in the open position, and when the surface 11 of the main housing 1 is flush with the inner surface 23 of the pivot housing 2, the housing assembly can be used as an electronic dictionary as a result of the presence of the first display 12 and the keypads 32, as shown in FIG. 6.

It has thus been shown that the housing assembly of the present invention is suitable for a multi-function electronic device. Moreover, the rectangular configuration of the housing assembly of the present invention can facilitate carrying and handling of the same.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

1. A housing assembly for an electronic device, comprising:
a base housing having a pivot side and an inner operating surface;
a pivot housing connected pivotally to said pivot side of said base housing and having an outer operating surface, and an inner surface opposite to said outer operating surface, said pivot housing being rotatable relative to said base housing about a first axis such that said pivot housing is operable so as to move from a closed position, where said inner surface of said pivot housing is disposed to confront said inner operating surface of said base housing, to an open position, where said inner surface of said pivot housing is spaced apart from said inner operating surface of said base housing; and
a rotatable main housing disposed adjacent to said base housing and said pivot housing and connected rotatably to said pivot housing, said main housing being rotatable relative to said pivot housing about a second axis parallel to the first axis when said pivot housing is disposed in the open position.

2. The housing assembly as claimed in claim 1, wherein said main housing has opposite surfaces, one of which is adapted to be mounted with a first display of the electronic device thereon.

3. The housing assembly as claimed in claim 2, wherein the other one of said opposite surfaces of said main housing is adapted to be mounted with a second display of the electronic device thereon.

4. The housing assembly as claimed in claim 2, wherein one of said opposite surfaces of said main housing is formed with a speaker sound hole.

5. The housing assembly as claimed in claim 1, wherein at least one of said outer operating surface and said inner surface of said pivot housing is formed with a microphone sound hole.

6. The housing assembly as claimed in claim 2, wherein one of said opposite surfaces of said main housing is adapted to be mounted with a camera lens thereon.

7. The housing assembly as claimed in claim 1, wherein said outer operating surface of said pivot housing is adapted to be mounted with a set of function keys thereon.

8. The housing assembly as claimed in claim 1, wherein said inner operating surface of said base housing is adapted to be mounted with a keypad thereon.

9. The housing assembly as claimed in claim 1, wherein said pivot housing has a first side connected pivotally to said pivot side of said base housing, and a second side transverse to said first side, said main housing being connected rotatably to said second side of said pivot housing.

10. The housing assembly as claimed in claim 9, wherein said second axis is disposed at a center of said second side.

11. The housing assembly as claimed in claim 9, wherein said main housing has a third side parallel to said pivot side of said base housing and transverse to said second side of said pivot housing, said pivot side of said base housing having a length equal to sum of a length of said third side of said main housing and that of said first side of said pivot housing.
